(19) United States
(12) Patent Application Publication
(10) Pub. No.: US 2020/0088815 A1
(43) Pub. Date: Mar. 19, 2020

(54) MAGNETIC RESONANCE IMAGING APPARATUS

(71) Applicant: SAMSUNG ELECTRONICS CO., LTD., Suwon-si, (KR)

(72) Inventors: Man Ho JEONG, Suwon-si (KR); Byoeng Su KIM, Yongin-si (KR); Ku Cheol AHN, Guri-si (KR)

(73) Assignee: SAMSUNG ELECTRONICS CO., LTD., Suwon-si, (KR)

(21) Appl. No.: 16/483,906

(22) PCT Filed: Nov. 20, 2017
(86) PCT No.: PCT/KR2017/013159

§ 371 Date: Aug. 6, 2019

(30) Foreign Application Priority Data
Feb. 6, 2017 (KR) 10-2017-0016115

(51) Int. Cl. G01R 33/30

(52) U.S. Cl. CPC G01R 33/307

(57) ABSTRACT

The present disclosure relates to a magnetic resonance imaging apparatus. The magnetic resonance imaging apparatus includes a magnetic assembly having a cavity, a cradle on which an object is located and configured to be movable to the inside or outside of the cavity, a cradle guide configured to guide the movement of the cradle, and a buffer member configured to be expandable in at least a part of a space between the cradle and the cradle guide.

### TECHNICAL FIELD

The present disclosure relates to a magnetic resonance imaging apparatus, and more particularly, to a magnetic resonance imaging apparatus having improved image quality.

### BACKGROUND ART

Generally, a medical imaging apparatus is an apparatus for obtaining information of a patient and providing an image. Medical imaging apparatuses include an X-ray apparatus, an ultrasonic diagnostic apparatus, a computerized tomography apparatus, a magnetic resonance imaging apparatus and the like.

Among these apparatuses, the magnetic resonance imaging apparatus has an important role in the field of diagnosis using medical images because the magnetic resonance imaging apparatus is relatively free of imaging conditions and provides excellent contrast and diagnostic information on various images of soft tissues.

Magnetic Resonance Imaging (MRI) is the imaging of the atomic nucleus density and physico-chemical properties by generating a nuclear magnetic resonance phenomenon on a hydrogen nucleus in a human body using a magnetic field free from harm to the human body and RF which is non-ion zing radiation.

Specifically, the magnetic resonance imaging apparatus supplies a constant frequency and energy to a cavity in a state of applying a constant magnetic field, converts energy emitted from an atomic nucleus into a signal, and images the interior of an object.

The magnetic resonance imaging apparatus uses various kinds of pulse sequences to obtain images, and thus various types of vibrations occur in gradient coils (G-Coil) of a magnet assembly. These vibrations cause inconvenience to a patient and deteriorate the quality of an image.

### DISCLOSURE

### Technical Problem

The present disclosure is directed to providing a magnetic resonance imaging apparatus capable of reducing vibration transmitted to a cradle.

### Technical Solution

One aspect of the present disclosure provides a magnetic resonance imaging apparatus including a magnetic assembly having a cavity; a cradle on which an object is seated and configured to be movable to the inside or outside of the cavity; a cradle guide configured to guide the movement of the cradle; and a buffer member configured to be expandable in at least a part of a space between the cradle and the cradle guide.

The buffer member may be set to a first mode in which the buffer member is expanded by injecting a fluid into the inside of the buffer member when the cradle stops and may be set to a second mode in which the buffer member is contracted by removing the fluid from the inside of the buffer member when the cradle moves along the cradle guide.

The buffer member may be set to the first mode when the cradle stops inside the cavity.

The buffer member may be set to the first mode when the magnet assembly forms a magnetic field.

The magnetic resonance imaging apparatus may further include a pressure regulating device connected to the buffer member and including a pressurizing pump configured to inject a fluid into the buffer member.

The pressure regulating device may further include a decompressing pump configured to be connected to the buffer member to remove the fluid from the buffer member.

The magnetic resonance imaging apparatus may further include a vibration sensor configured to detect vibration information of the cradle, wherein the vibration information may include at least one of the magnitude and direction of vibration generated in the cradle.

The pressure regulating device may be configured to regulate an amount of fluid to be injected into the buffer member corresponding to the vibration information of the cradle detected by the vibration sensor.

The buffer member may include a plurality of buffer elements, and the pressure regulating device may be configured to individually inject the fluid into each of the plurality of buffer elements corresponding to the vibration information of the cradle detected by the vibration sensor.

At least some buffer elements of the plurality of buffer elements may be expanded in a different direction than the other buffer elements.

The cradle may include a roller configured to roll on the cradle guide and to support the movement of the cradle.

The roller may be in contact with the cradle guide when the buffer member is contracted and may be released from the contact with the cradle guide when the buffer member is expanded.

The roller may include a first roller member configured to support the cradle in the gravity direction and a second roller member configured to support the cradle in a direction perpendicular to the gravity direction and the moving direction of the cradle.

The buffer member may include a material having elasticity.

The magnetic resonance imaging apparatus may further include a controller controlling the pressure regulating device, wherein the controller may be configured to control the pressure regulating device according to vibration information stored in advance.

Another aspect of the present disclosure provides a magnetic resonance imaging apparatus including a magnetic assembly having a cavity; a cradle on which an object is located and configured to be movable to the inside or outside of the cavity; a cradle guide configured to guide the movement of the cradle; a roller configured to support the movement of the cradle; and a buffer member configured to be expandable between the cradle and the cradle guide, wherein the buffer member is expanded when the magnetic assembly forms a magnetic field.

The magnetic resonance imaging apparatus may further include a pressure regulating device configured to regulate an amount of a fluid inside the buffer member.

The roller may be in contact with the cradle or the cradle guide when the buffer member is contracted and may be released from the contact with the cradle or the cradle guide when the buffer member is expanded.

The buffer member may be contracted when the cradle moves.

Another aspect of the present disclosure provides a magnetic resonance imaging apparatus including a magnetic assembly having a cavity; a cradle on which an object is located and configured to be movable to the inside or outside of the cavity; a cradle guide configured to guide the movement of the cradle; and a buffer member configured to be in contact with the cradle and the cradle guide when the magnetic assembly forms a magnetic field and to be released from the contact with the cradle or the cradle guide when the cradle moves on the cradle guide.

### Advantageous Effects

According to an aspect of the present disclosure, a magnetic resonance imaging apparatus can reduce the vibration transmitted from a gradient coil of a magnet assembly to a cradle, thereby improving the quality of an image.

According to an aspect of the present disclosure, the magnetic resonance imaging apparatus can reduce the vibration transmitted from the gradient coil of the magnet assembly to the cradle, thereby eliminating the inconvenience that a patient may feel.

### DESCRIPTION OF DRAWINGS

FIG. 1 is a schematic view of a magnetic resonance imaging apparatus according to an embodiment of the present disclosure.

FIG. 2 is a view illustrating a state in which an object is transferred to the inside of a cavity in a scanner shown in FIG. 1.

FIG. 3 is a view illustrating a lower surface of a cradle shown in FIG. 1.

FIG. 4 is a view illustrating an upper surface of the cradle with a cover removed, shown in FIG. 1.

FIG. 5 is a cross-sectional view taken along line A-A′ shown in FIG. 1.

FIG. 6 is a cross-sectional view taken along line B-B′ shown in FIG. 1.

FIG. 7 is a view illustrating a state in which a buffer member shown in FIG. 6 is expanded.

### BEST MODE OF THE INVENTION

### Mode of the Invention

The presentation describes the principles of the present disclosure and discloses embodiments in order to clarify the scope of the present disclosure and to enable a person skilled in the art to carry out the present disclosure. The disclosed embodiments may be implemented in various forms.

Like reference numerals refer to like elements throughout this specification. This specification does not describe all components of the embodiments, and general contents in the technical field to which the present disclosure belongs or overlapping contents between the embodiments will not be described. The terms “part” and “portion” as used herein, may be implemented as software or hardware, and according to embodiments, a plurality of “parts” or “portions” may be implemented as a single unit or element, or a single “part” or “portion” may include a plurality of elements.

The image herein may include a medical image acquired by a medical imaging apparatus, such as a magnetic resonance imaging (MRI) apparatus, a computed tomography (CT) apparatus, an ultrasonic imaging apparatus, or an x-ray imaging apparatus.

In this specification, an “object” may be a person, an animal, or a part thereof, which is an object of photography. For example, an object may include a part of the body (organ) or a phantom.

A magnetic resonance imaging apparatus obtains a magnetic resonance (MR) signal, and reconstructs the acquired tic resonance signal into an image. The magnetic resonance signal refers to an RF signal emitted from an object.

In the magnetic resonance imaging apparatus, the main magnet forms a static magnetic field, and aligns the directions of the magnetic dipole moments of the specific atomic nuclei of the object located in the static magnetic field in the direction of the static magnetic field. The gradient magnetic field coil may apply a gradient signal to the static magnetic field to form a gradient magnetic field, and may induce different resonance frequencies for each part of the object.

The RF coil may emit an RF signal to match the resonance frequency of a site where the image acquisition is desired. Further, as the gradient magnetic field is formed, the RF coil may receive MR signals of different resonance frequencies radiated from various sites of the object. Through these steps, the magnetic resonance imaging apparatus acquires an image from the MR signal using an image restoration technique.

Hereinafter embodiments according to the present disclosure will be described in detail with reference to the accompanying drawings.

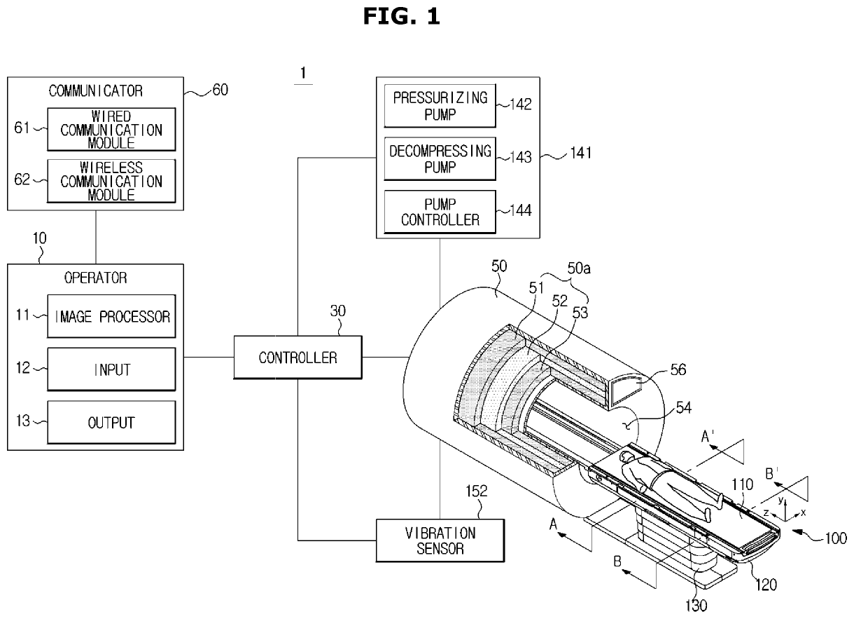

FIG. 1 is a schematic view of a magnetic resonance imaging apparatus 1.

Referring to FIG. 1, the magnetic resonance imaging apparatus 1 may include an operator 10, a controller 30, and a scanner 50. The controller 30 may be implemented independently as shown in FIG. 1. Alternatively, the controller 30 may be divided into a plurality of components and included in each component of the magnetic resonance imaging apparatus 1. Hereinafter each component will be described in detail.

The scanner 50 may be implemented as a shape (for example, a bore shape) in which the internal space thereof is empty so that an object may be inserted. A static magnetic field and a gradient magnetic field are formed in the internal space of the scanner 50, and an RF signal is emitted to the internal space. The internal space into which the object is inserted may be referred to as a cavity 54.

The scanner 50 may include a static magnetic field forming portion 51, a gradient magnetic field forming portion 52, an RF coil portion 53, a table unit 100, and a display 56. The static magnetic field forming portion 51 forms a static magnetic field for aligning the directions of the magnetic dipole moments of the atomic nuclei included in the object in the static magnetic field direction. The static magnetic field forming portion 51 may be implemented as a permanent magnet or a superconducting magnet that uses a cooling coil.

The gradient magnetic field forming portion 52 is connected to the controller 30. The gradient magnetic field forming portion 52 forms a gradient magnetic field by applying a gradient to the static magnetic field according to the control signal transmitted from the controller 30. The gradient magnetic field forming portion 52 includes X, Y, and Z coils forming gradient magnetic fields in the X-axis, Y-axis, and Z-axis directions orthogonal to each other, and generates gradient signals in accordance with the photographing positions to induce different resonance frequencies for each part of the object.

The RF coil portion 53 is connected to the controller 30 and may emit an RF signal to an object according to a control signal transmitted from the controller 30 and receive an MR signal emitted from the object. The RE coil portion 53 may transmit an RF signal with a frequency equal to the frequency of precession motion to the object toward an atomic nucleus carrying out a precession motion and then stop the transmission of the RF signal, and may receive the MR signal emitted from the object.

The RF coil portion 53 may be implemented as a transmitting RF coil for generating an electromagnetic wave having a radio frequency corresponding to the type of atomic nucleus and a receiving RF coil for receiving the electromagnetic wave radiated from the atomic nucleus or may be implemented as one RF transmission/reception coil having both a transmitting function and a receiving function. In addition to the RF coil portion 53, a separate coil may also be mounted on the object. For example, a head coil, a spine coil, a torso coil, a knee coil, or the like may be used as the separate coil depending on a shooting region or a mounting region.

The display 56 may be provided on the outside and/or inside of the scanner 50. The display 56 may be controlled by the controller 30 to provide a user or the object with information related to medical imaging.

The scanner 50 may be provided with an object monitoring information obtainer (not shown) for obtaining and transmitting monitoring information on the condition of the object. For example, the object monitoring information obtainer may obtain monitoring information on an object from a camera (not shown) that photographs a motion, a position, and the like of the object, a respiration meter knot shown) measuring the respiration of the object, an ECG measuring device (not shown) for measuring the electrocardiogram of the object, or a body temperature measuring device (not shown) for measuring the body temperature of the object, and may transmit the monitoring information to the controller 30. Accordingly, the controller 30 may control the operation of the scanner 50 using the monitoring information on the object. Hereinafter the controller 30 will be described.

The controller 30 may control the overall operation of the scanner 50.

The controller 30 may control a sequence of signals formed inside the scanner 50. The controller 30 may control the gradient magnetic field forming portion 52 and the RF coil portion 53 according to a pulse sequence received from the operator 10 or a designed pulse sequence.

The pulse sequence includes all information necessary for controlling the gradient magnetic field forming portion 52 and the RE coil portion 53. For example, the pulse sequence may include information on the intensity of the pulse signal applied to the gradient magnetic field forming portion 52, the duration of application, the timing of application, and the like.

The controller 30 may control a waveform generator (not shown) for generating a gradient waveform, that is, a current pulse in accordance with the pulse sequence and a gradient amplifier (not shown) that amplifies the generated current pulse and transmits the amplified current pulse to the gradient magnetic field forming portion 52 to control the formation of the gradient magnetic field of the gradient magnetic field forming portion 52.

The controller 30 may control the operation of the RF coil portion 53. For example, the controller 30 may supply an RF pulse of a resonance frequency to the RF coil portion 53 to emit the RF signal, and receive the MR signal received by the RF coil portion 53. At this time, the controller 30 may control the operation of a switch (for example, a T/R switch) capable of regulating the transmission/reception direction through the control signal to control the irradiation of the RF signal and the reception of the MR signal according to the operation mode.

The controller 30 may control the movement of the table unit 100 in which the object is located. Before the imaging is performed, the controller 30 may move the table unit 100 in advance in accordance with the imaging region of the object. Details of the table unit 100 will be described later.

The controller 30 may control the display 56. For example, the controller 30 may control on/off of the display 56 through a control signal, or a screen or the like displayed through the display 56.

The controller 30 may be implemented with an algorithm for controlling the operation of components in the magnetic resonance imaging apparatus 1, a memory (not shown) for storing program type data, and a processor (not shown) for performing the above-described operation using data stored in the memory. In this case, the memory and the processor may be implemented as separate chips. Alternatively, the memory and the processor may he implemented as a single chip.

The operator 10 may control the overall operation of the magnetic resonance imaging apparatus 1. The operator 10 may include an image processor 11, an input 12, and an output 13.

The image processor 11 may store e MR signal received from the controller 30 using the memory and apply an image restoration technique using an image processor to generate image data for the object from the stored MR signal.

For example, when k-space data is completed by filling the k-space (for example, Fourier space or frequency space) of the memory with digital data, the operator 10 may restore the k-space data into image data by applying various image restoration techniques (for example, inverse Fourier transform of k-space data) through an image processor.

Various signal processes applied to the MR signal by the image processor 11 may be performed in parallel. For example, a plurality of MR signals received by a multi-channel RF coil may be subjected to signal processing in parallel to be restored into image data. The restored image data may be stored in the memory by the image processor 11 or may be stored in an external server through a communicator 60 by the controller 30, which will be described later

The input 12 may receive a control command related to the overall operation of the magnetic resonance imaging apparatus 1 from the user. For example, the input 12 may receive object information, parameter information, scan conditions, information on pulse sequences, and the like from the user. The input 12 may be implemented as a keyboard, a mouse, a trackball, a voice recognizer, a gesture recognizer, a touch screen, or the like.

The output 13 may output the image data generated by the image processor 11. The output 13 may also output a user interface (UI) configured to allow the user to input a control command related to the magnetic resonance imaging apparatus 1. The output 13 may be implemented as a speaker, a printer, a display, or the like.

FIG. 1 illustrates a configuration in which the operator 10 and the controller 30 are separated from each other. However, as described above, the operator 10 and the controller 30 may be included in one device. Further, the processes performed by each of the operator 10 and the controller 30 may be performed in other components. For example, the image processor 11 may convert the MR signal received by the controller 30 into a digital signal, or the controller 30 may directly convert the MR signal into a digital signal.

The magnetic resonance imaging apparatus 1 includes the communicator 60, and may be connected to an external device (not shown) (for example, a server, a medical device, a portable device (smartphone, tablet PC, wearable device, etc.)) through the communicator 60.

The communicator 60 may include one or more components that enable communication with an external device. For example, the communicator 60 may include at least one of a local communication module (not shown), a wired communication module 61, and a wireless communication module 62.

The communicator 60 may also receive a control signal and data from an external device and transmit the received control signal to the controller 30 so that the controller 30 controls the magnetic resonance imaging apparatus 1 in accordance with the received control signal.

Alternatively, the controller 30 may transmit a control signal to an external device through the communicator 60, thereby controlling the external device in accordance with the control signal of the controller.

For example, the external device may process data of the external device according to the control signal of the controller 30 received through the communicator 60.

The external device may be provided with a program capable of controlling the magnetic resonance imaging apparatus 1, and the program may include commands for performing part or all of the operation of the controller 30.

The program may be installed in advance in the external device, or a user of the external device may download and install the program from a server providing the application.

Components of the magnetic resonance imaging apparatus 1 may be separately arranged in a scanning room, a machine room, and an operating room. For example, the scanner 50 may be located in the scanning room, the controller 30 and a pressure regulating device 141 may be located in the machine room, and the operator 10 may be located in the operating room. However, such arrangement is changeable as needed.

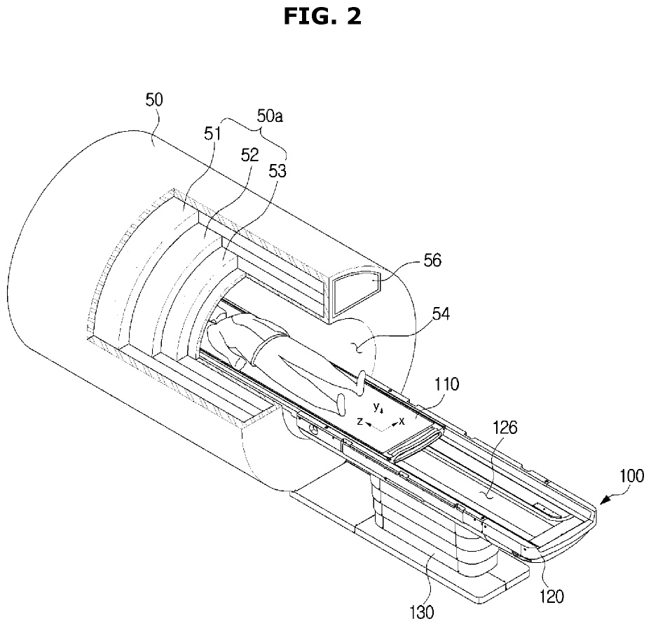

FIG. 2 is a view illustrating a state in which an object is transferred to the inside of the cavity 54 in the scanner 50 shown in FIG. 1.

The table unit 100 may include a cradle 110 on which the object is seated and which moves the object into or out of the cavity 54, a cradle guide 120 for guiding the movement of the cradle 110, and a fixed table 130 for supporting the cradle guide 120.

The fixed table 130 is connected to a magnet assembly 50a including the static magnetic field forming portion 51, the gradient magnetic field forming portion 52 and the RF coil portion 53, and may support the cradle guide 120 in a fixed state. Accordingly, when vibration is generated in the magnet assembly 50a, the vibration may be transmitted from the magnet assembly 50a to the fixed table 130, and the vibration transmitted to the fixed table 130 may be transmitted to the cradle guide 120.

A portion of the cradle guide 120 may be fixed to an upper portion of the fixed table 130. Alternatively, the cradle guide 120 may be integrally formed with the fixed table 130. An upper surface of the cradle guide 120 may be provided in a shape substantially similar to a lower surface of the cradle 110. The cradle guide 120 may include a cradle seating portion 126 formed to be recessed on the upper surface thereof. The cradle guide 120 may extend to the cavity 54 inside the magnet assembly 50a.

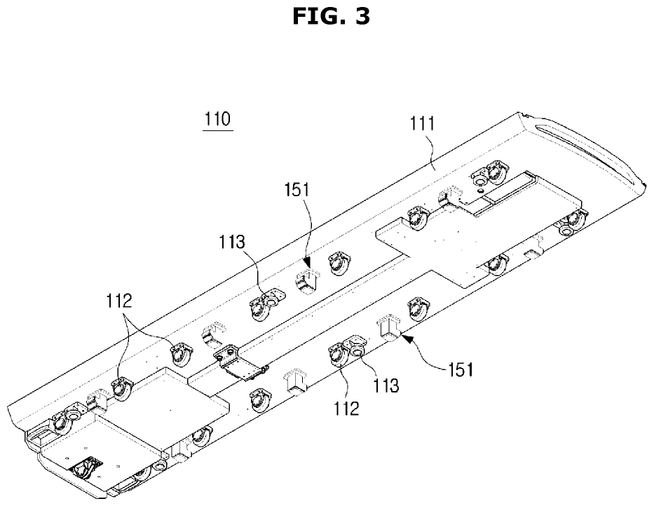

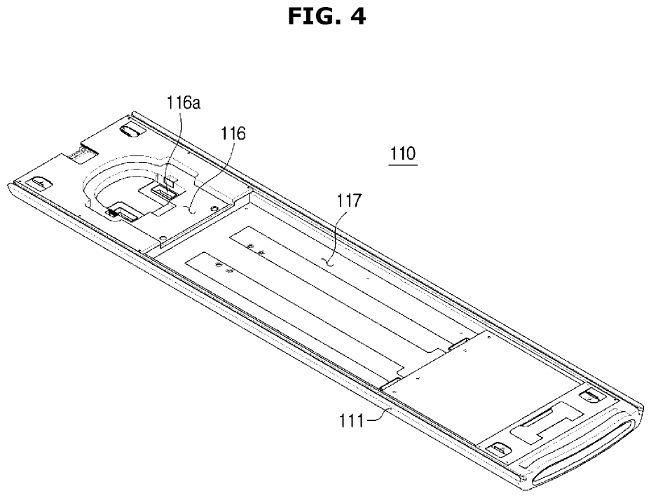

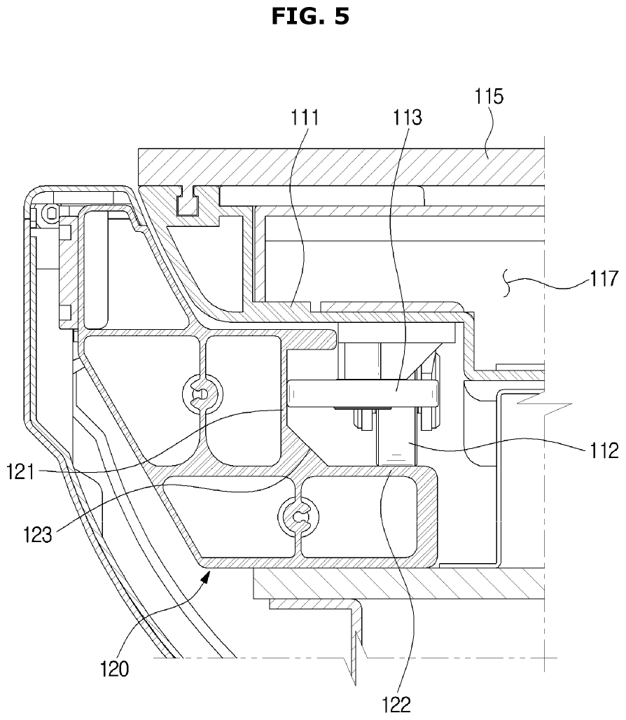

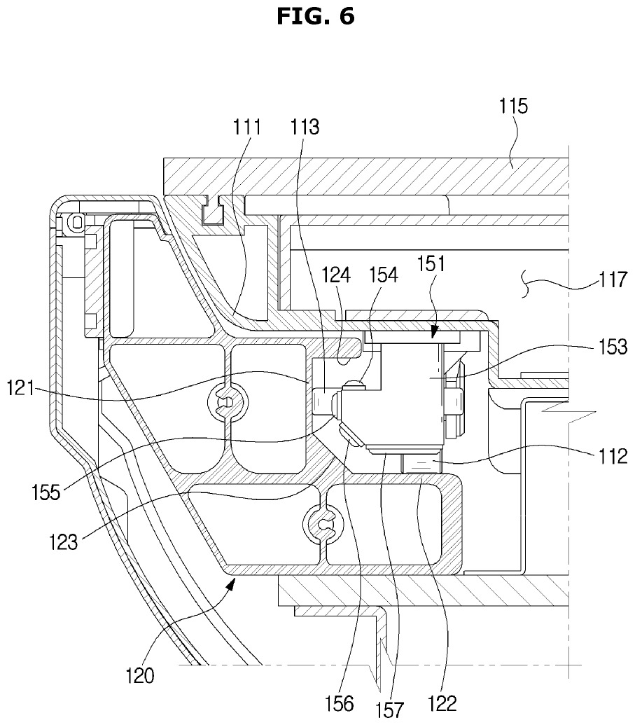

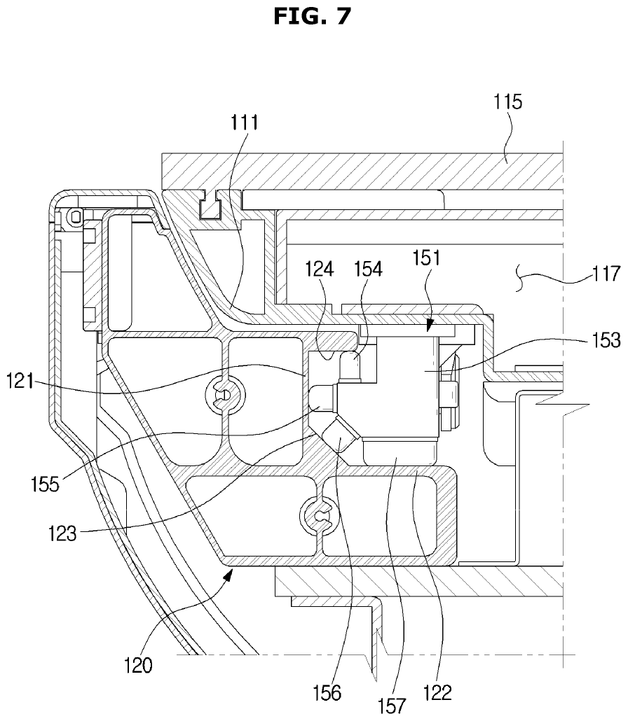

FIG. 3 is a view illustrating the lower surface of the cradle 110 shown in FIG. 1. FIG. 4 is a view illustrating an upper surface of the cradle 110 with a cover 115 removed, shown in FIG. 1. FIG. 5 is a cross-sectional view taken along line A-A′ shown in FIG. 1. FIG. 6 is a cross-sectional view taken along line B-B′ shown in FIG. 1. FIG. 7 is a view illustrating a state in which a buffer member shown in FIG. 6 is expanded.

The cradle 110 may be provided to be movable on the cradle guide 120. The cradle 110 may be moved on the cradle guide 120 by receiving a driving force from a belt or the like. The cradle 110 may include a case 111 and the cover 115 coupled to an upper portion of the case 111. Accommodating spaces 116 and 117 in which electric components may be disposed may be provided in the case 111. Rollers 112 and 113 for supporting the movement of the cradle 110 may be provided on the upper surface of the cradle 110.

Referring to FIGS. 3 and 5, the rollers 112 and 113 may be rolled along at least one surface of the cradle seating portion 126 of the cradle guide 120 so that the cradle 110 may move on the cradle guide 120. The rollers 112 and 113 allow the cradle 110 to move with minimal friction on the cradle guide 120.

Although the present embodiment illustrates that the rollers 112 and 113 are provided on the cradle 110, it is not limited thereto. That is, the rollers 112 and 113 may be provided on the cradle seating portion 126 of the cradle guide 120, and in this case the cradle 110 may be moved on the rollers provided on the cradle guide 120.

The rollers 112 and 113 may include the first roller member 112 for supporting the cradle 110 in the gravity direction, and the second roller member 113 for supporting the cradle 110 in the gravity direction and in a direction perpendicular to the moving direction of the cradle 110. That is, the second roller member 113 may be provided to support the movement of the cradle 110 to the right and left when the direction in which the cradle 110 moves is referred to as a forward and backward direction. In addition, a plurality of the first roller members 112 and/or second roller members 113 may be provided in an arbitrary order along the longitudinal direction of the cradle 110.

Accordingly, the first roller members 112 may in contact with a first surface 122 of the cradle seating portion 126 and the second roller members 113 may in contact with a second surface 121 of the cradle seating portion 126.

However, as described above, because the cradle 110 is in contact with the cradle guide 120 by the rollers 112 and 113, the vibration transmitted to the cradle guide 120 may be directly transmitted to the cradle, and such vibration may not only cause inconvenience to the object placed on the cradle 110 but also may lower the quality of the image when the image is shot.

In order to solve this problem, the magnetic resonance imaging apparatus 1 according to an embodiment of the present disclosure may include a buffer member 151 and the pressure regulating device 141 connected to the buffer member 151 to inject a fluid into the buffer member 151.

The pressure regulating device 141 may regulate the amount of the fluid inside the buffer member 151. The pressure regulating device 141 may be disposed in the machine room. The pressure regulating device 141 may include a pressurizing pump 142 capable of injecting the fluid into the buffer member 151, a decompressing pump 143 capable of removing the fluid from the buffer member 151, and a pump controller 144 capable of controlling the pressurizing pump 142 and the decompressing pump 143.

The pressurizing pump 142 may expand the buffer member 151 by injecting the fluid into the buffer member 151. At this time, the fluid may be air. The decompressing pump 143 may shrink the buffer member 151 by removing the fluid from the inside of the buffer member 151.

On the other hand, although not shown, the pressure regulating device 141 may not include the decompressing pump 143. In this case, the amount of the fluid inside the buffer member 151 may be regulated only by the pressurizing pump 142.

Referring to FIG. 4, when the pressure regulating device 141 is disposed in the machine room, a tube (not shown) for connecting the pressure regulating device 141 and the buffer member 151 may be disposed in the first accommodating space 116. Specifically, the tube extending from the machine room may extend through the fixed table 130 and the cradle guide 120, and then through an opening 116a to the first accommodating space 116. The tube extending to the first accommodating space 116 may be connected to respective buffer elements 154, 155, 156, and 157 through the second accommodating space 117. The tube through which the fluid moves may extend along the same route as a cable connecting the controller 30 and the magnet assembly 50a.

The first accommodating space 116 and the second accommodating spaces 117 may be protected from the outside by the cover 115.

The buffer member 151 may be configured to reduce the vibration transmitted to the cradle 110 through the cradle guide 120. The buffer member 151 may be configured to selectively release the direct contact between the rollers 112 and 113 and the cradle guide 120. A plurality of the buffer members 151 may be provided along the longitudinal direction of the cradle 110. The buffer member 151 may include a body 153, which will be described later, connected to the pressure regulating device 141, and a plurality of the buffer elements 154, 155, 156, and 157 communicating with the body 153.

The body 153 may include a plurality of openings (not shown) to communicate with the plurality of buffer elements 154, 155, 156, and 157, respectively. Accordingly, the fluid delivered from the pressure regulating device 141 to the body 153 may be distributed to each of the plurality of buffer elements 154, 155, 156, and 157 by a required amount.

Referring to FIG. 7, the buffer member 151 may be provided to be expandable in at least a part of a space between the cradle 110 and the cradle guide 120. To this end, the buffer member 151 may be configured to include a material having elasticity. Although FIG. 3 illustrates that the buffer member 151 is provided on the lower surface of the cradle 110, the buffer member 151 may be provided on the cradle seating portion 126 of the cradle guide 120.

The buffer member 151 may expand when the fluid is injected by the pressure regulating device 141, which will be described later, and thus the buffer member 151 may be in contact with at least one surface of the cradle seating portion 126 of the cradle guide 120.

The buffer member 151 may be set to a first mode in which the buffer member 151 expands as the fluid is injected into the buffer member 151 when the cradle 110 does not move but stops. Specifically, the buffer member 151 may be set to the first mode when the cradle 110 is stopped inside the cavity 54. More specifically, the buffer member 151 may be set to the first mode when the magnetic assembly 50a forms a magnetic field for photographing. That is, when the magnetic resonance imaging apparatus 1 photographs the object, the buffer member 151 may reduce vibration by being in contact with the cradle guide 120 so that the vibration transmitted to the cradle guide 120 is not transmitted to the cradle 110.

On the other hand, referring to FIG. 6, the buffer member 151 may be set to a second mode in which the buffer member 151 is contracted as the fluid is removed from the inside of the buffer member 151 when the buffer member 151 moves along the cradle guide 120. That is, when the magnetic resonance imaging apparatus 1 does not photograph the object, the buffer member 151 may not be in contact with the cradle guide 120 so that the cradle 110 may freely move on the cradle guide 120.

With the above configuration, the magnetic resonance imaging apparatus 1 according to an embodiment of the present disclosure may reduce vibration transmitted to the cradle 110 by the buffer member 151 when photographing the object, thereby preventing inconvenience to the object and improving the quality of the image, and may not interfere with the movement of the cradle 110 when the cradle 110 moves on the cradle guide 120.

That is, when the buffer member 151 is contracted, the rollers 112 and 113 may be in contact with the cradle guide 120, and when the buffer member 151 is expanded, the rollers 112 and 113 may be separated from the cradle guide 120 by a predetermined distance and the contact with the cradle guide 120 may be released.

The buffer member 151 may include a plurality of the buffer elements 154, 155, 156 and 157. The plurality of buffer elements 154, 155, 156, and 157 may be provided to be expanded in different directions, respectively. The plurality of buffer elements 154, 155, 156, 157 may each be individually expanded.

With the above configuration, the magnetic resonance imaging apparatus 1 according to an embodiment of the present disclosure may obtain an optimum buffering effect in response to various vibrations. That is, the magnetic resonance imaging apparatus 1 may effectively reduce vibrations in various directions transmitted from the magnet assembly 50a to the cradle 110 by individually regulating an amount of fluid injected into each of the buffer elements 154, 155, 156, and 157 in view of the vibration information including the direction of vibration and/or the intensity of vibration.

Specifically, the magnetic resonance imaging apparatus 1 may effectively reduce vibrations transmitted to the cradle 110 by injecting a large amount of fluid into the buffer elements 154, 155, 156, and 157 corresponding to the direction of vibration.

For example, referring to FIGS. 6 and 7, when the cradle 110 undergoes vibration in the left and right direction, only the buffer element 155 among the plurality of buffer elements 154, 155, 156, and 157 may be expanded to be brought into contact with the second surface 121. On the other hand, when the cradle 110 undergoes vibration in the up and down direction, only the buffer elements 154 and 157 among the plurality of buffer elements 154, 155, 156, and 157 may be expanded to be brought into contact with the first surface 122 and a third surface 124. Further, when the cradle 110 undergoes vibration in a lower diagonal direction (i.e., approximately 7 o'clock in the drawing), only the buffer element 156 among the plurality of buffer elements 154, 155, 156, and 157 may be expanded to be brought into contact with a four surface 123.

In addition, by injecting a large amount of fluid into the buffer elements 154, 155, 156, and 157 corresponding to the portion undergoing strong vibration, the vibration transmitted to the cradle 110 may be effectively reduced.

For example, when the cradle 110 undergoes a strong vibration in the left and right direction but a weak vibration in the up and down direction, a relatively large amount of fluid may be injected into the buffer element 155 among the plurality of buffer elements 154, 155, 156, and 157 and a relatively small amount of fluid may be injected into the buffer elements 154 and 157 among the plurality of buffer elements 154, 155, 156, and 157.

The cradle 110 may be provided with a vibration sensor 152 for detecting vibration information of the cradle 110. The vibration information may include the magnitude of the vibration and/or the direction of the vibration transmitted to the cradle 110.

The vibration sensor 152 may sense information on the vibration of the cradle 110 and transmit the detected vibration information to the pump controller 144. The pump controller 144 may control the pressurizing pump 142 and/or the decompressing pump 143 in real time in response to the received vibration information.

Specifically, when the vibration sensor 152 detects a strong vibration and transmits the strong vibration to the pump controller 144, the pump controller 144 may control the pressurizing pump 142 and/or the decompressing pump 143 to increase the amount of fluid injected into the buffer member 151. On the other hand, when the vibration sensor 152 detects a weak vibration and transmits the weak vibration to the pump controller 144, the pump controller 144 may control the pressurizing pump 142 and/or the decompressing pump 143 to decrease the amount of fluid injected into the buffer member 151.

Alternatively, the pump controller 144 may control the pressure regulating device 141 according to vibration information stored in advance. Specifically, the pump controller 144 includes in advance information on an amount of fluid to be injected into the pressurizing pump 142 and/or the decompressing pump 143 according to various vibrations and may, when the user inputs a region of the object desired to be photographed through the input 12, inject the fluid into the buffer member 151 based on the information stored in advance according to the inputted command.

As described above, although only a case where the buffer member 151 includes a material having elasticity to be expanded or contracted by the pressure regulating device 141 has been described, the buffer member 151 may be configured in such a manner that the plurality of buffer elements 154, 155, 156, and 157 is extended from the inside of the body 153 or retracts into the inside of the body 153.

Specifically, the plurality of buffer elements 154, 155, 156, and 157 may be formed of a material having elasticity and may be provided such that a portion thereof may move to the inside or the outside of the body 153. Accordingly, as illustrated in FIG. 6, when the cradle 110 moves on the cradle guide 120, the plurality of buffer elements 154, 155, 156, and 157 may be retracted into the inside of the body 153 in order not to be in contact with the cradle guide 120, and as illustrated in FIG. 7, when the cradle 110 is disposed in the cavity 54 to photograph the object, the plurality of buffer elements 154, 155, 156 and 157 may be extended toward the cradle guide 120 in order to be in contacted with the cradle guide 120. In this case, as described above, the plurality of buffer elements 154, 155, 156, and 157 may be provided to extend in mutually different directions and may be provided to extend from the body 153 individually corresponding to the direction and/or magnitude of the vibration transmitted to the cradle 110. In addition, a driving unit for extending or retracting the plurality of buffer elements 154, 155, 156, and 157 from or into the inside of the body 153 may be provided inside the body 153.

Accordingly, the magnetic resonance imaging apparatus 1 may reduce the vibration generated from the magnet assembly 50a and transmitted to the cradle 110 when photographing the object, thereby preventing inconvenience to the object and improving the quality of the image.

The disclosed embodiments may be implemented in the form of a computer-readable recording medium that stores instructions and data executable by a computer. The instructions may be stored in the form of program code, and when executed by a processor, may perform a predetermined operation generate a predetermined program module. In addition, the instructions, when executed by the processor, may perform predetermined operations of the disclosed embodiments.

The embodiments disclosed with reference to the accompanying drawings have been described above. It will be understood by those skilled in the art that various changes in form and details may be made therein without departing from the spirit and scope of the disclosure as defined by the appended claims. The disclosed embodiments are illustrative and should not be construed as limiting.

1. A magnetic resonance imaging apparatus comprising:
a magnetic assembly having a cavity;
a cradle on which an object is seated and configured to be movable to the inside or outside of the cavity;
a cradle guide configured to guide the movement of the cradle; and
a buffer member configured to be expandable in at least a part of a space between the cradle and the cradle guide.

2. The magnetic resonance imaging apparatus according to claim 1, wherein
the buffer member is set to a first mode in which the buffer member is expanded by injecting a fluid into the inside of the buffer member when the cradle stops, and set to a second mode in which the buffer member is contracted by removing the fluid from the inside of the buffer member when the cradle moves along the cradle guide.

3. The magnetic resonance imaging apparatus according to claim 2, wherein
the buffer member is set to the first mode when the cradle stops inside the cavity.

4. The magnetic resonance imaging apparatus according to claim 2, wherein
the buffer member is set to the first mode when the magnet assembly forms a magnetic field.

5. The magnetic resonance imaging apparatus according to claim 1, further comprising
a pressure regulating device connected to the buffer member and including a pressurizing pump configured to inject a fluid into the buffer member.

6. The magnetic resonance imaging apparatus according to claim 5, wherein
the pressure regulating device further includes a decompressing pump configured to be connected to the buffer member to remove the fluid from the buffer member.

7. The magnetic resonance imaging apparatus according to claim 5, further comprising
a vibration sensor configured to detect vibration information of the cradle,
wherein the vibration information includes at least one of the magnitude and direction of vibration generated in the cradle.

8. The magnetic resonance imaging apparatus according to claim 7, wherein
the pressure regulating device is configured to regulate an amount of fluid to be injected into the buffer member corresponding to the vibration information of the cradle detected by the vibration sensor.

9. The magnetic resonance imaging apparatus according to claim 7, wherein
the buffer member includes a plurality of buffer elements, and
the pressure regulating device is configured to individually inject the fluid into each of the plurality of buffer elements corresponding to the vibration information of the cradle detected by the vibration sensor.

10. The magnetic resonance imaging apparatus according to claim 9, wherein
at least some buffer elements of the plurality of buffer elements are expanded in a different direction than the other buffer elements.

11. The magnetic resonance imaging apparatus according to claim 1, wherein
the cradle includes a roller configured to roll on the cradle guide and to support the movement of the cradle.

12. The magnetic resonance imaging apparatus according to claim 11, wherein
the roller is in contact with the cradle guide when the buffer member is contracted, and released from the contact with the cradle guide when the buffer member is expanded.

13. The magnetic resonance imaging apparatus according to claim 11, wherein
the roller includes a first roller member configured to support the cradle in the gravity direction and a second roller member configured to support the cradle in a direction perpendicular to the gravity direction and the moving direction of the cradle.

14. The magnetic resonance imaging apparatus according to claim 1, wherein
the buffer member includes a material having elasticity.

15. The magnetic resonance imaging apparatus according to claim 5, further comprising
a controller controlling the pressure regulating device,
wherein the controller is configured to control the pressure regulating device according to vibration information stored in advance.
